(19) United States
(12) Patent Application Publication
(10) Pub. No.: US 2008/0042925 A1
(43) Pub. Date: Feb. 21, 2008

(54) Key assignable portable terminal device

(75) Inventors: Toshihiko Arai, Kawasaki (JP); Katsuaki Akama, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/645,510

(22) Filed: Dec. 27, 2006

(30) Foreign Application Priority Data
Aug. 15, 2006 (JP) 2006-221-371

(51) Int. Cl. H03M 11/00

(52) U.S. Cl. 345/22

(57) ABSTRACT

To provide a portable terminal device that can secure the same operability even when a user changes his or her portable terminal device to a new one, the portable terminal device is made to comprise a function providing unit for providing a function according to key inputs, a standard profile obtaining unit for obtaining a second standard profile from a communications destination device, etc., and a standard profile registering unit for registering the contents of the second standard profile to a first standard profile.

### BACKGROUND OF THE INVENTION

1. Field of the Invention

The present invention relates to a portable terminal device comprising a key assignment function for assigning a provided function to arbitrary keys.

2. Description of the Related Art

In recent years, portable terminal devices such as a cellular phone, a PDA (Personal Digital Assistant) and the like have rapidly become widespread.

For a portable terminal device, the number of keys that can be mounted is restricted due to constraints such as its size and the like. Accordingly, for example, a plurality of functions are assigned to a combination of one or more keys (this assignment is hereinafter referred to as “key assignment”).

The key assignment differs by maker or by type. Therefore, if a user changes a portable terminal device, to the operations of which he or she is accustomed for a long period of use, to a portable terminal device of a different maker or of a different type, the user must again learn the key assignment of the new portable terminal device and get accustomed to its key operations.

Japanese Unexamined Patent Application No. H08-249153 discloses an input operation converting device that can be operated also by a user, who is unaccustomed to the operations of a machine, based on natural inference, and can improve the operability of the machine. Additionally, Japanese Unexamined Patent Application No. 2001-265472 discloses an interface implementation method for implementing an interface, which is adjusted suitably for each user, regardless of the type of a used computer system or the like.

### SUMMARY OF THE INVENTION

The present invention was developed in consideration of the above described problem, and an object thereof is to provide a portable terminal device that can secure the same operability even if a user changes his or her portable terminal device to a new one.

To overcome the above described problem, a portable terminal device according to the present invention comprises a function providing unit for obtaining a function, which is assigned to a series of key inputs, from a first standard profile having first key assignment information where a predetermined function is assigned to each series of key inputs, and for providing the function, upon detection of the series of key inputs pressed in an arbitrary order as a combination of one or more keys, a standard profile obtaining unit for obtaining, from a different device or a storage medium, a second standard profile having second key assignment information where a predetermined function is assigned to each series of key inputs, and a standard profile registering unit for obtaining the second key assignment information from the second standard profile and for registering the second key assignment information to the first standard profile.

Here, the “different device” means a portable terminal device, a server or the like. “Obtaining from a different device or a storage medium” means that the second standard profile may be obtained from a different device connected to be communicable via a wired or wireless communication, or the second standard profile, which is copied from the different device to a storage medium, may be obtained by being read from the storage medium.

According to the present invention, the standard profile obtaining unit obtains the second standard profile having key assignment information of a different device (such as an accustomed portable terminal device used so far) via a communication or a storage medium, and the standard profile registering unit registers the contents of the second standard profile to the first standard profile, which is key assignment information of the portable terminal device (such as a newly used portable terminal device). As a result, also the portable terminal device can be operated with operations similar to those of the different device.

As described above, according to the present invention, a portable terminal device, which can secure the same operability, can be provided even if a user changes his or her portable terminal device to a new one.

### BRIEF DESCRIPTION OF THE DRAWINGS

FIG. 1 is a schematic explaining the principle of operations of a portable terminal device according to a preferred embodiment of the present invention;

FIG. 2 is a functional block diagram showing a configuration of the portable terminal device according to the preferred embodiment of the present invention;

FIG. 3 is a schematic explaining a first or second standard profile according to the preferred embodiment of the present invention;

FIG. 4 is a schematic exemplifying the structure of function operation information shown in FIG. 3;

FIG. 5 is a flowchart showing a standard profile generation process according to the preferred embodiment of the present invention;

FIG. 6 is a flowchart showing a standard profile registration process according to the preferred embodiment of the present invention;

FIG. 7 is a flowchart showing a specific example of the standard profile registration process shown in FIG. 6; and

FIG. 8 is a flowchart showing a process performed by the portable terminal device according to the preferred embodiment of the present invention in response to a series of key inputs made by a user.

### DESCRIPTION OF THE PREFERRED EMBODIMENTS

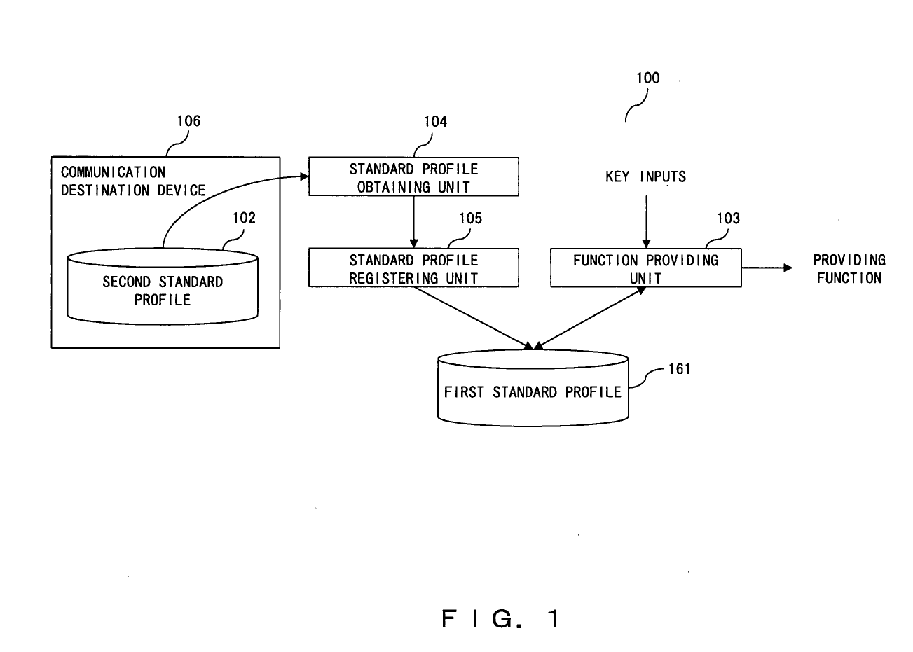

A preferred embodiment according to the present invention is hereinafter described with reference to FIGS. 1 to 8.

FIG. 1 is a schematic explaining the principle of operations of the portable terminal device 100 according to the preferred embodiment of the present invention.

The portable terminal device 100 shown in this figure comprises a function providing unit 103 for providing a function according to a key input, a standard profile obtaining unit 104 for obtaining a second standard profile 102 from a communications destination device 106, etc., and a standard profile registering unit 105 for registering the contents of the second standard profile 102 to a first standard profile 101.

The first standard profile 101 is configured by information about the operations of the portable terminal device 100. In this preferred embodiment, the first standard profile 101 is configured by first key assignment information where a predetermined function is assigned to each series of key inputs.

The “series of key inputs” means key inputs with which a combination of one or more keys such as a MENU key, dial keys 0 to 9, etc. are input in an arbitrary order.

Similarly, the second standard profile 102 is configured by information about the operations of the communications destination device 106. In this preferred embodiment, the second standard profile 102 is configured by second key assignment information where a predetermined function is assigned to each series of key inputs.

The function providing unit 103 references the first standard profile 101 upon detection of a series of key inputs. Then, the function providing unit 103 obtains the function assigned to the detected series of key inputs, and executes a program stored in a storing unit not shown in order to provide the function.

In the meantime, the standard profile obtaining unit 104 is a unit for obtaining the second standard profile 102. The second standard profile 102 may be obtained, for example, from the communications destination device 106 by making a connection to be communicable with the communications destination device 106. Or, the second standard profile 102 may be obtained via a storage medium.

“Obtaining the second standard profile 102 via a storage medium” means that the second standard profile, which is written from the communications destination device 106 to the storage medium, is obtained by being read from the storage medium.

The standard profile registering unit 105 reflects the second key assignment information in the second standard profile 102 on the first standard profile 101 (this process is hereinafter referred to as “registration”).

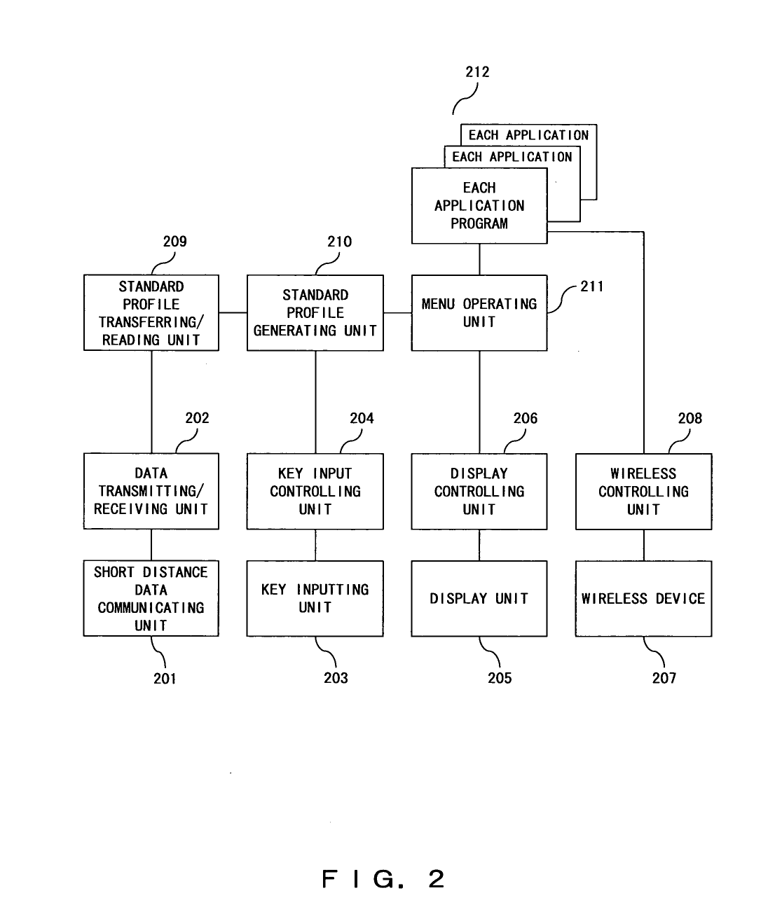

FIG. 2 is a functional block diagram showing a configuration of the portable terminal device 100 according to the preferred embodiment of the present invention.

The portable terminal device 100 shown in this figure comprises a short distance data communicating unit 201 for making a data communication in a short distance, a data transmitting/receiving unit 202 for transmitting/receiving data by controlling the short distance data communicating unit 201, a key inputting unit 203 for detecting the press, etc. of an input key, a key input controlling unit 204 for controlling an input key, a display unit 205 for displaying data, a display controlling unit 206 for controlling the display unit 205, a wireless device 207 for making a wireless communication such as a cellular phone, etc., a wireless controlling unit 208 for making a connection to be communicable with a predetermined device via a portable terminal communications network, etc., a standard profile transferring/reading unit 209 for transferring/receiving a standard profile via the short distance data communicating unit 201, a standard profile generating unit 210 for generating/registering a standard profile, and a menu operating unit 211 for executing a program 212 according to a key input notified from the key input controlling unit 204 to provide a function intended by a user.

The standard profile transferring/reading unit 209 makes a connection to be communicable with a different portable terminal device via the short distance data communicating unit 201, and transfers/receives the second standard profile 102.

The standard profile generating unit 210 obtains a function, which is assigned to a series of key inputs detected by the key inputting unit 203, from the first standard profile 101 stored in a memory, etc. not shown. Then, the standard profile generating unit 210 instructs the menu operating unit 211 to execute the function.

Additionally, the standard profile generating unit 210 registers the contents of the second standard profile 102 received by the standard profile transferring/reading unit 209 to the first standard profile 101.

The menu operating unit 211 controls the entire portable terminal device, and displays functions on the display unit 205. Additionally, the menu operating unit 211 reads, from a storing unit not shown, a program 212 for implementing the function instructed from the standard profile generating unit 210, and executes the program.

In the above described configuration, the standard profile transferring/reading unit 209, the standard profile generating unit 210 and the menu operating unit 211 are implemented by causing a CPU, which is comprised by the portable terminal device 100 and not shown, to execute a predetermined program.

The short distance data communicating unit 201 and the data transmitting/receiving unit 202 are implemented, for example, by a short distance communications device of IrDA (Infrared Data Association), RF-ID (Radio Frequency Identification) or the like.

In the above described configuration, the function providing unit 103 shown in FIG. 1 is implemented by the key input controlling unit 204 and the menu operating unit 211, and the standard profile registering unit 105 is implemented by the menu operating unit 211. Additionally, the standard profile obtaining unit 104 is implemented by the standard profile transferring/reading unit 209.

In this preferred embodiment, the second standard profile 102 is obtained from a different portable terminal device by making a communication of IrDa, etc. using the short distance data communicating unit 201. However, the second standard profile 102 may be obtained from a different portable terminal device, a server or the like via a network by comprising a network connecting unit as a replacement for the short distance data communicating unit 201. Or, the second standard profile 102 may be obtained via a portable storage medium by comprising a medium driving unit for driving the portable storage medium as a replacement for the short distance data communicating unit 201.

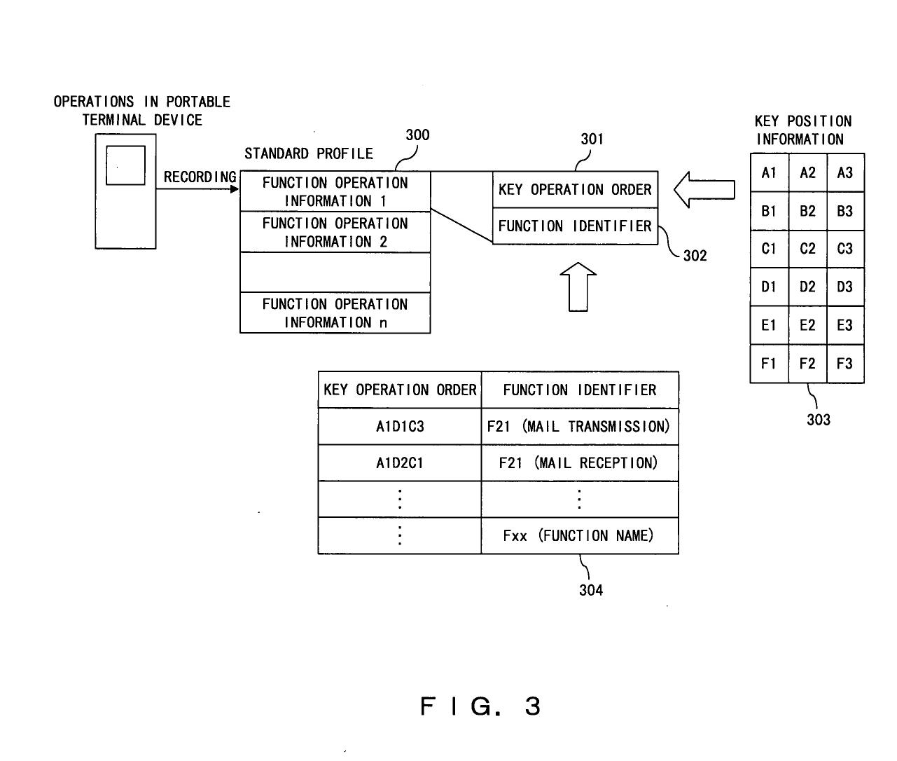

FIG. 3 is a schematic explaining the first or the second standard profile according to the preferred embodiment of the present invention.

The first or the second standard profile (hereinafter referred to simply as a “standard profile 300”) shown in FIG. 3 include one or more pieces of function operation information (key assignment information) 1 to n. The function operation information 1 to n respectively include a key operation order 301 detected from a series of key inputs, and a function identifier 302.

The key operation order 301 is information indicating a series of key inputs pressed by a user and their order. The portable terminal device 100 detects an input key each time a user presses an arbitrary key. Then, the position information of an input key (such as a key [A1] or the like) is obtained in a detected order by referencing key position information 303, and the obtained position information is stored as key operation order 301.

For example, when input keys are detected in an order of keys [A1], [D2] and [C1], the key operation order 301 becomes “A1D2C1”.

The key position information 303 is information indicating the position of a key comprised by the portable terminal device 100, and associated with an interrupt signal of each key. By way of example, the keys [A1], [D2] and [C1] respectively indicate the positions of a menu key, and dial keys [5] and [1].

The function identifier 302 is information for identifying a function provided by the portable terminal device 100. After obtaining the key operation order 301, the portable terminal device 100 obtains the function identifier (such as F21 or the like) of the function assigned to the key operation order 301 by referencing a function identifier list 304, and stores the function identifier.

Assuming that the key operation order 301 is “A2D2C1”, “F22”, which is the identifier of a mail reception function, is stored as the function identifier 302.

The function identifier list 304 is configured by the key operation order 301, and a function identifier for identifying a function which is assigned to each key operation order 301 and provided by the portable terminal device 100. In FIG. 3, for example, F22 (mail reception) is assigned to “A1D2C1”.

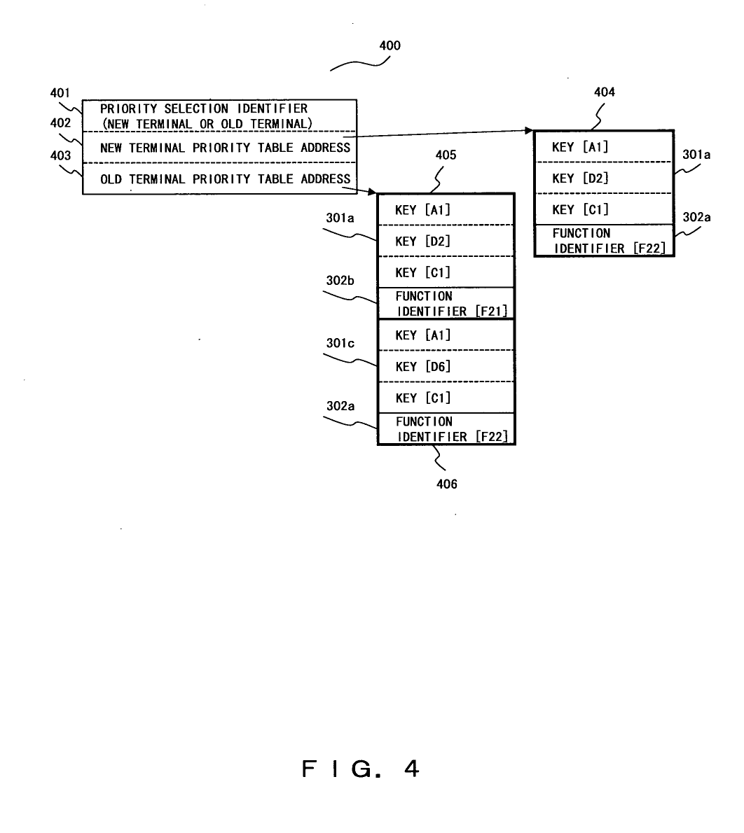

FIG. 4 is a schematic exemplifying a structure of the function operation information shown in FIG. 3.

The function operation information 400 shown in FIG. 4 includes a priority selection identifier 401, a new terminal priority table address 402, and an old terminal priority table address 403.

The priority selection identifier 401 is a function assigned to a predetermined key, and is information indicating a function, which is used with higher priority among functions assigned to a portable terminal device that a user starts to newly use (hereinafter referred to as a “new portable terminal device”) or functions assigned to a portable terminal device that the user uses prior to the new portable terminal device (hereinafter referred to as an “old portable terminal device”).

If a function assigned to the new portable terminal device is used with higher priority, “new terminal” is set. Or, if a function assigned to the old portable terminal device is used with higher priority, “old terminal” is set.

The new terminal priority table address 402 is address information indicating the storage destination of a new terminal function conversion table 404 that stores a key operation order 301a of a new portable terminal device, and a function identifier 302a of the function assigned to the key operation order 301a.

The new terminal function conversion table 404 shown in FIG. 4 shows a case where the keys [A1], [D2] and [C1] are stored as the key operation order 301a, and the identifier [F22] is stored as the function identifier 302a.

The old terminal priority table address 403 is address information indicating the storage destination of an old terminal function conversion table 405 that stores a key operation order 301a of an old portable terminal device, and a function identifier 302b of the function assigned to the key operation order 301a.

If the key operation order 301a of the new portable terminal device (and the function identifier 302a of the function assigned to the key operation order 301a) are already registered when a priority is given to the old terminal, a duplicate function conversion table 406 is added to the old terminal function conversion table 405, and the function identifier 302a is assigned to a key operation order 301c, to which a function is not yet assigned, and stored.

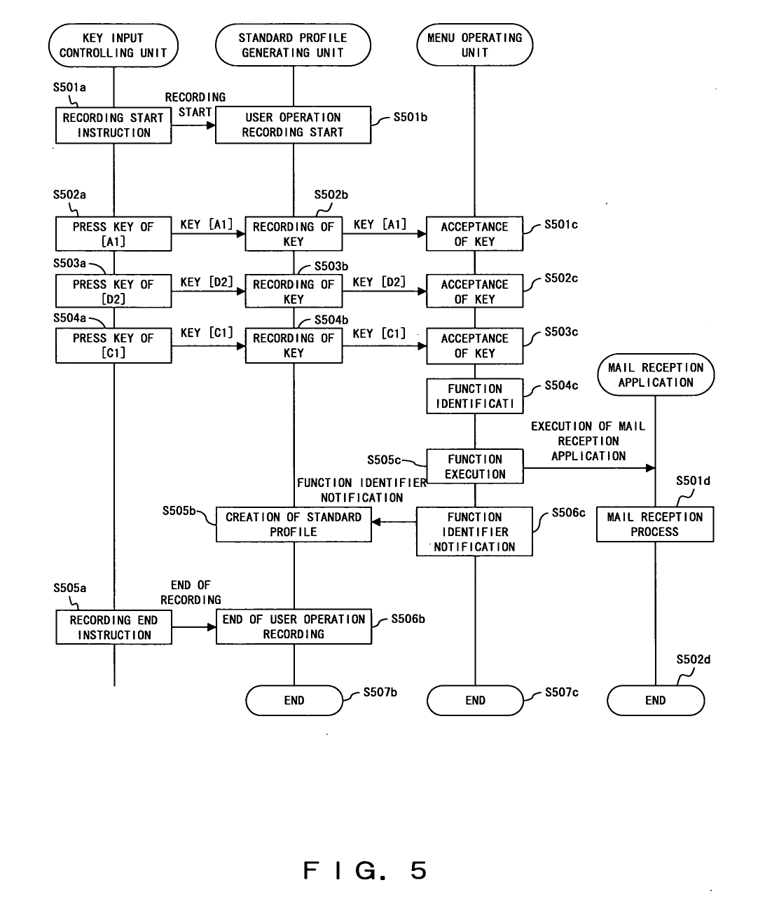

FIG. 5 is a flowchart showing a standard profile generation process according to the preferred embodiment of the present invention.

The flowchart shown in this figure represents the standard profile generation process when a user performs key operations for pressing keys in the order of the keys [A1], [D2] and [C1] on the portable terminal device 100, for ease of understanding of the process.

When the user performs a predetermined operation on the portable terminal device 100, the portable terminal device 100 detects a recording start instruction in step S501a. Then, the portable terminal device 100 notifies the standard profile generating unit 210 of an operation recording start instruction.

Upon acceptance of the operation recording start instruction, the standard profile generating unit 210 starts to record key operations performed by the user in step S501b.

When the user performs the series of key input operations (inputs in the order of the keys [A1], [D2] and [C1]), the key input controlling unit 204 notifies the standard profile generating unit 210 of the detected keys in steps S502a to S504a.

When the input keys are notified, the standard profile generating unit 210 stores the input keys in the order notified from the key input controlling unit 204, and notifies the menu operating unit 211 of the input keys in steps S502b to S504b.

The menu operating unit 211 accepts the input keys notified from the standard profile generating unit 210, and temporarily stores this series of key inputs in the memory, etc. in steps S501c to S503c.

In step S504c, the menu operating unit 211 references the function identifier list 304, identifies the function assigned to the series of key inputs obtained in steps S501c to S503c, and obtains the function identifier of the function.

In step S505c, the menu operating unit 211 executes a program for implementing the function identified in step S504c. FIG. 4 shows the case where the mail reception function is assigned to the series of key inputs [A1], [D2] and [C1]. Therefore, the menu operating unit 211 executes the application program for mail reception in step S505c.

The application (the application for mail reception in FIG. 5) executed by the menu operating unit 211 performs the mail reception process in step S501d. Then, the process advances to step S502d, in which the process is ended.

Additionally, in step S506c, the menu operating unit 211 notifies the standard profile generating unit 210 of the function identifier obtained in step S504c, and ends the process.

The standard profile generating unit 210, which is notified of the function identifier, advances the process to step S505b. Then, the standard profile generating unit 210 stores the series of key inputs (the keys [A1], [D2] and [C1] in FIG. 5) obtained in steps S502b to S504b and the function identifier notified from the menu operating unit 211 as the key operation order 301 and the function identifier 302, which are shown in FIG. 3. If the new terminal function conversion table 404 and the old terminal function conversion table 405 are comprised as shown in FIG. 4, the series of key inputs and the function identifier may be stored, for example, in the old terminal function conversion table 405.

When the user performs a predetermined operation on the portable terminal device 100, the portable terminal device 100 detects a recording end instruction in step S505a. Then, the portable terminal device 100 notifies the standard profile generating unit 210 of an operation recording end instruction.

Upon acceptance of the operation recording end instruction, the standard profile generating unit 210 ends the recording of key operations of the user in step S506b.

FIG. 5 shows only the case where the series of key inputs is made in the order of [A1], [D2] and [C1] for ease of understanding of the process. However, the key inputs are not limited to this case as a matter of course. Also when a series of arbitrary key inputs is made, a similar process is performed. Additionally, FIG. 5 shows the case of the three consecutive key inputs. However, two or more consecutive key inputs may be allowed.

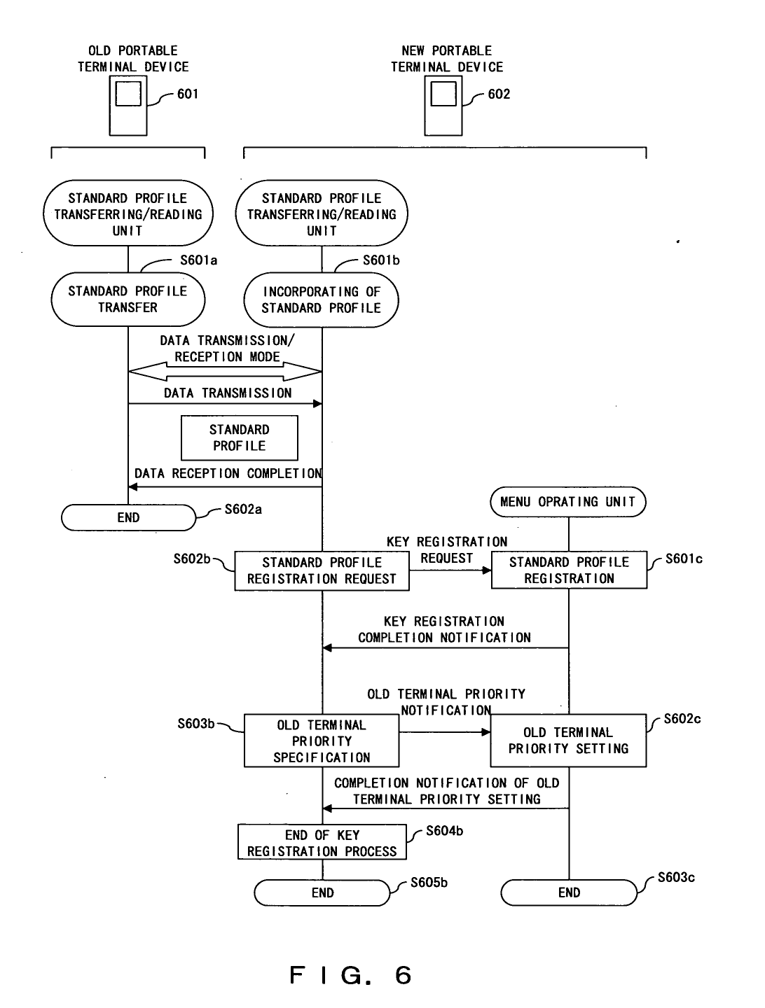

FIG. 6 is a flowchart showing a standard profile registration process according to the preferred embodiment of the present invention.

This figure shows the process for obtaining a standard profile (hereinafter referred to as the “first standard profile”) generated by the old portable terminal device, and for incorporating the first standard profile into a standard profile (hereinafter referred to as the “second standard profile”) possessed by the new portable terminal device.

In step S601a, the old portable terminal device 601 makes a connection to be communicable with the new portable terminal device 602 via the short distance data communicating unit 201 when starting a standard profile transfer process. The state at this time is called data transmission/reception mode.

In the data transmission/reception mode, the old portable terminal device 601 transmits the first standard profile to the new portable terminal device 602. When data reception completion is notified from the new portable terminal device 602, the old portable terminal device 601 releases the data transmission/reception mode, and ends the standard profile transfer process.

In the meantime, the new portable terminal device 602 enters the data transmission/reception mode by request from the old portable terminal device 601 in step S601b. Upon receipt of the first standard profile from the old portable terminal device 601, the standard profile transferring/reading unit 209 of the new portable terminal device 602 returns the data reception completion notification, and releases the data transmission/reception mode. Then, the standard profile transferring/reading unit 209 advances the process to step S602b.

In step S602b, the standard profile transferring/reading unit 209 issues a request to start the standard profile registration process to the menu operating unit 211.

Upon acceptance of the request to start the standard profile registration process from the standard profile transferring/reading unit 209, the menu operating unit 211 starts the standard profile registration process to register the contents of the first standard profile to the second standard profile in step S601c.

Upon completion of the standard profile registration process, the menu operating unit 211 notifies the standard profile transferring/reading unit 209 of the standard profile registration completion.

Upon receipt of the standard profile registration completion notification, the standard profile transferring/reading unit 209 advances the process to step S603b. Then, the standard profile transferring/reading unit 209 instructs the menu operating unit 211 to set an old terminal priority as a priority mode.

Upon acceptance of the old terminal priority notification, the menu operating unit 211 advances the process to step S602c. Next, the menu operating unit 211 sets the old terminal priority as the priority mode of the second standard profile. Then, the menu operating unit 211 notifies the standard profile transferring/reading unit 209 of the completion of the old terminal priority setting, and ends the process.

Upon receipt of the notification of the completion of the old terminal priority setting from the menu operating unit 211, the standard profile transferring/reading unit 209 advances the process to step S604b, and ends the standard profile registration process.

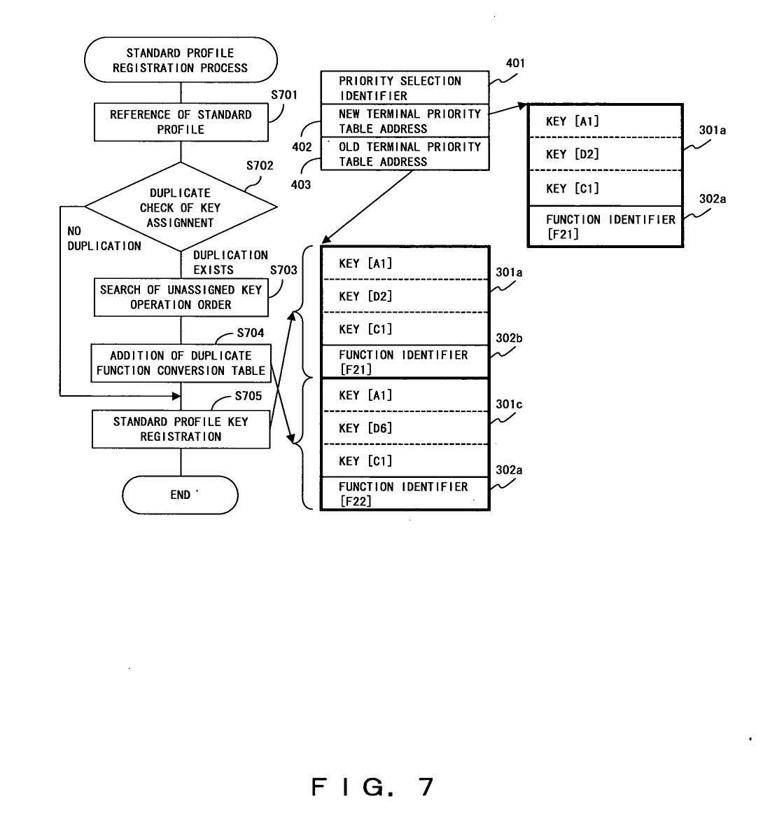

FIG. 7 is a flowchart showing a specific example of the standard profile registration process (S601c) shown in FIG. 6.

In step S601c shown in FIG. 6, the menu operating unit 211 transfers the process to step S701 upon acceptance of the standard profile registration request.

In step S701, the menu operating unit 211 references the first standard profile obtained from the old portable terminal device 601. Then, the menu operating unit 211 obtains the key operation order 301a registered to the old terminal function conversion table 405 of the first standard profile.

In step S702, the menu operating unit 211 references the second standard profile, and searches the key operation order that matches the key operation order 301a obtained in step S701. Upon detection of the matching key operation order, the menu operating unit 211 advances the process to step S703.

In step S703, the menu operating unit 211 references the second standard profile to search a key operation order 301c to which a function is not assigned.

In step S704, the menu operating unit 211 adds the duplicate function conversion table 406 to the old terminal function conversion table 405. Then, the menu operating unit 211 registers the new key operation order 301c detected in step S703 and the function identifier 302a assigned to the key operation order 301a detected in step S702 to the duplicate function conversion table 406.

In step S705, the menu operating unit 211 registers the key operation order 301a obtained in step S701 and the function identifier 302b assigned to the key operation order 301a to the old terminal function conversion table 405. Then, the menu operating unit 211 advances the process to step S706, and ends the process.

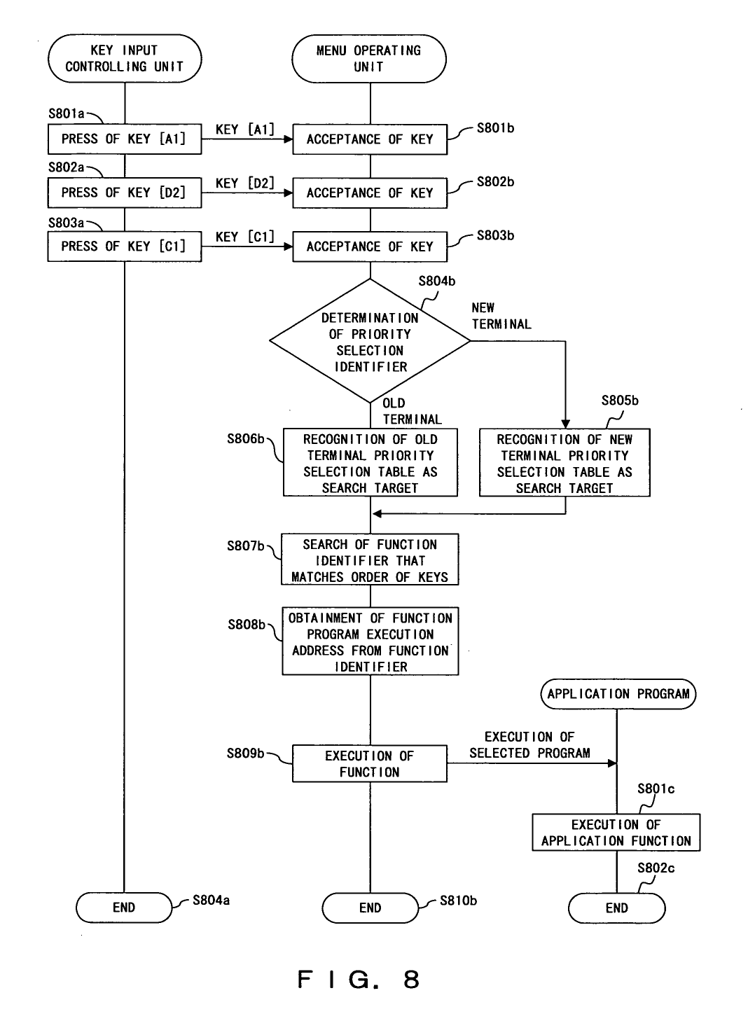

FIG. 8 is a flowchart showing a process performed by the portable terminal device 100 according to the preferred embodiment of the present invention in response to a series of key inputs made by a user.

The flowchart shown in this figure represents the process performed by the portable terminal device 100 when a user performs the key operations for pressing keys in the order of the keys [A1], [D2] and [C1], for ease of understanding of the process. However, the key inputs are not limited to this case as a matter of course. A similar process is performed also when a series of arbitrary key inputs is made.

When the user performs the series of key input operations (inputs in the order of the keys [A1], [D2] and [C1]), the key input controlling unit 204 notifies the menu operating unit 211 of the detected keys in steps S801a to S803a.

In the meantime, the menu operating unit 211 accepts the key inputs notified from the key input controlling unit 204, and temporarily stores the series of key inputs in the memory, etc. in steps S801b to S803b. Then, the menu operating unit 211 advances the process to step S804b.

In step S804b, the menu operating unit 211 references the first standard profile 101 stored in the memory, etc. to search function operation information having the key operation order 301a that matches the series of key inputs accepted in steps S801b to S803b. Then, the menu operating unit 211 obtains a priority selection identifier 401 set in the function operation information, and determines the priority mode.

If “new terminal” is set as the priority selection identifier 401 (this case is hereinafter referred to as “new terminal priority mode”), the menu operating unit 211 transfers the process to step S805b. Then, the menu operating unit 211 obtains the new terminal priority table address 402.

Or, if “old terminal” is set as the priority selection identifier 401 (this case is hereinafter referred to as “old terminal priority mode”), the menu operating unit 211 advances the process to step S806b. Then, the menu operating unit 211 obtains the old terminal priority table address 403.

In step S807b, the menu operating unit 211 references the new terminal function conversion table 404 or the old terminal function conversion table 405 (including the duplicate function conversion table 406. The same is applied hereinafter), which is stored at the address obtained in step S805b or S806b, and obtains a function identifier.

Namely, if the priority mode is the new terminal priority mode, the menu operating unit 211 references the new terminal function conversion table 404 to obtain the function identifier 302a.

Or, if the priority mode is the old terminal priority mode, the menu operating unit 211 references the old terminal function conversion table 405 or the duplicate function conversion table 406 to obtain a function identifier having the key operation order that matches the series of key inputs obtained in steps S801b to S803b.

In step S808b, the menu operating unit 211 references a function identifier correspondence program table that defines a relationship between a function identifier and an address at which a program for implementing the function is stored (hereinafter referred to as a “program execution address”), and obtains the program execution address corresponding to the function identifier obtained in step S807b.

In step S809b, the menu operating unit 211 executes the program at the program execution address obtained in step S808b. Since the series of key inputs [A1], [D2] and [C1] is assigned to the mail reception function in this preferred embodiment, the program for implementing the mail reception function is executed. After the program is executed, the menu operating unit 211 advances the process to step S810b, and ends the process.

When the program is executed, mail reception is made in step S801c. Then, the process advances to step S802c, and the program process is ended.

In the above provided description, the second standard profile is obtained from the old portable terminal device 601. However, for example, a second standard profile prepared beforehand in a predetermined server or the like may be obtained via a network or the like.

As described above, the portable terminal device 100 according to this preferred embodiment can detect key inputs from a user, and can record the series of key inputs and a function assigned to the series of key inputs to a standard profile (FIG. 5).

Additionally, a second standard profile generated by a different portable terminal device is obtained via a communication or the like, and a series of key inputs recorded to the second standard profile and a function assigned to the series of key inputs can be incorporated into a first standard profile possessed by a local portable terminal device (FIG. 6).

Then, the portable terminal device 100 according to this preferred embodiment provides the function according to the inputs of a user in accordance with the first standard profile (FIG. 8), whereby operations similar to those in an accustomed portable terminal device can be performed also in a new portable terminal device.

What is claimed is:

1. A portable terminal device, comprising:
a function providing unit for obtaining a function, which is assigned to a series of key inputs, from a first standard profile having first key assignment information where a predetermined function is assigned to each series of key inputs, and for providing the function, upon detection of the series of key inputs pressed in an arbitrary order as a combination of one or more keys;
a standard profile obtaining unit for obtaining, from a different device or a storage medium, a second standard profile having second key assignment information where a predetermined function is assigned to each series of key inputs; and
a standard profile registering unit for obtaining the second key assignment information from the second standard profile, and for registering the second key assignment information to the first standard profile.

2. The portable terminal device according to claim 1, wherein
if a series of key inputs in the first key assignment information and a series of key inputs in the second key assignment information are duplicate, the standard profile registering unit registers the second key assignment information for the series of key inputs, and also registers the first key assignment information for a new series of key inputs.

3. The portable terminal device according to claim 1, wherein
the first and the second key assignment information include a plurality of pieces of information, each of which pairs a series of input keys pressed in an arbitrary order with a function identifier of a function associated with the series of input keys.

4. The portable terminal device according to claim 2, wherein
any one of the first key assignment information and the second key assignment information, which are registered to the first standard profile, is selected on demand, a function assigned to a series of key inputs is obtained from the selected key assignment information, and a program for implementing the function is executed.

5. A key assignment method for use in a portable terminal device, comprising:
reading from a storing unit a first standard profile having first key assignment information where a predetermined function is assigned to each series of key inputs;
obtaining, from a different device or a storage medium, a second standard profile having second key assignment information where a predetermined function is assigned to each series of key inputs; and
obtaining the second key assignment information from the second standard profile, and registering the second key assignment information to the first standard profile.

6. The key assignment method according to claim 5, further comprising
obtaining a function, which is assigned to a series of detected key inputs, from the first standard profile, and providing the function, upon detection of the series of key inputs pressed in an arbitrary order as a combination of one or more keys.

7. The key assignment method according to claim 5, wherein
if a series of key inputs in the first key assignment information and a series of key inputs in the second key assignment information are duplicate, the second key assignment information is registered for the series of key inputs, and also the first key assignment information is registered for a new series of key inputs in said registering.

8. The key assignment method according to claim 5, wherein
the first and the second key assignment information include a plurality of pieces of information, each of which pairs a series of input keys pressed in an arbitrary order with a function identifier of a function associated with the series of input keys.

9. The key assignment method according claim 7, wherein
any one of the first key assignment information and the second key assignment information, which are registered to the first standard profile, is selected on demand, a function assigned to a series of key inputs is obtained from the selected key assignment information, and a program for implementing the function is executed.

10. A storage medium on which is recorded a key assignment program for causing a portable terminal device to execute a process, the process comprising:
reading a first standard profile from a first standard profile storing unit for storing the first standard profile having first key assignment information where a predetermined function is assigned to each series of key inputs;
obtaining, from a different device or a storage medium, a second standard profile having second key assignment information where a predetermined function is assigned to each series of key inputs, and storing the second standard profile in a second standard profile storing unit; and
obtaining the second key assignment information from the second standard profile by reading the second standard profile from the second standard profile storing unit, and registering the second key assignment information to the first standard profile.

11. The storage medium according to claim 10, the process further comprising
identifying a function, which is assigned to a series of detected key inputs, from the first standard profile, and executing a program for implementing the function, upon detection of the series of key inputs pressed in an arbitrary order as a combination of one or more keys.

12. The storage medium according to claim 10, wherein
if a series of key inputs in the first key assignment information and a series of key inputs in the second key assignment information are duplicate, the second key assignment information is registered for the series of key inputs, and also the first key assignment information is registered for a new series of key inputs in said registering.

13. The storage medium according to claim 10, wherein
the first and the second key assignment information include a plurality of pieces of information, each of which pairs a series of input keys pressed in an arbitrary order with a function identifier of a function associated with the series of input keys.

14. The storage medium according to claim 12, wherein
any one of the first key assignment information and the second key assignment information, which are registered to the first standard profile, is selected on demand, a function assigned to a series of key inputs is obtained from the selected key assignment information, and a program for implementing the function is executed.
